(19) United States
(12) Patent Application Publication
(10) Pub. No.: US 2009/0061367 A1
(43) Pub. Date: Mar. 5, 2009

(54) APPLIANCE HAVING A SAFETY STRING

(76) Inventors: Andrew Robert Caves, Milwaukee, WI (US); Andrew William Phillips, Columbia, SC (US); Brian Thomas Branecky, Oconomowoc, WI (US); William Louis Mehlhorn, Menomonee Falls, WI (US); Thomas Gerard Van Sistine, Menomonee Falls, WI (US); John Matthew Schulz, Franklin, TN (US)

Correspondence Address: MICHAEL BEST & FRIEDRICH LLP, 100 E WISCONSIN AVENUE, Suite 3300, MILWAUKEE, WI, 53202, US

(21) Appl. No.: 12/021,416

(22) Filed: Jan. 29, 2008

Related U.S. Application Data
(60) Provisional application No. 60/968,424, filed on Aug. 28, 2007.

(51) Int. Cl. F23N 5/24; G01R 31/08

(52) U.S. Cl. 431/22; 324/522

(57) ABSTRACT

A gas-fired appliance is disclosed that includes a gas valve powered by a power source. A plurality of switching units, each responsive to a condition of the appliance, are arranged in series between the gas valve and the power source. Each switching unit includes an emitter, such as an emitter of an optocoupler, that is used to monitor the opened or closed status of a switch in the switching unit. When at least one switch opens, power to the gas valve is reduced preventing the gas valve from operating. However, because this reduced power is provided to each subsequent switching unit, each optocoupler can be monitored regardless of the opened or closed status of previous switching units. As such, one or more open switches can be detected simulataneously.

### RELATED APPLICATIONS

This patent application claims the benefit of U.S. provisional patent application No. 60/968,424, filed on Aug. 28, 2007, the entirety of which is hereby incorporated by reference. This patent application also incorporates by reference the entire contents of co-pending U.S. patent application Ser. No. ______, filed on ______, 2008, entitled “APPLIANCE HAVING LOAD MONITORING SYSTEM” (Attorney Docket No. 010121-8165-00).

### FIELD OF THE INVENTION

The invention relates generally to appliances, such as gas-fired appliances, having safety limit strings, and more particularly to appliance controllers that monitor the state of the switches in a safety limit string to detect one or more simultaneous conditions in the appliance.

### BACKGROUND

Safety limit strings are known that include a plurality of switches arranged in series, each switch corresponding to an operating condition. Such safety limit strings are placed between a power source and a gas valve. When a fault condition is encountered, the related switch is opened and power is disconnected.

Systems and methods of monitoring such safety limit string in order to diagnose the specific fault condition are also known. Such systems generally include an electrical contact located before each switch and are monitored by a circuit, which may include a controller. When a switch in the safety limit string is opened in response to a fault condition, the controller can identify the open switch by detecting the last electrical contact in the safety limit string to receive power from the power source.

### SUMMARY

Among other deficiencies in some known safety limit string systems, previous systems are unable to detect and identify multiple fault conditions occurring simultaneously. Because the supply of electrical power is terminated when a first open switch is encountered, any subsequent open switches in the safety limit string are not detected.

One embodiment of the invention provides a gas-fired appliance that includes a first and a second switching unit placed in series between a power source and the gas valve. The first switching unit includes a switch circuit and a leakage circuit arranged in parallel. The leakage circuit includes a resistor and an emitter. When a switch opens in response to a condition in the appliance, current travels through the leakage circuit and a signal is emitted by the emitter. A receiver is positioned to receive any signals emitted from the emitter and communicate the signal to a microcontroller. The second switching unit can include similar components.

In some embodiments, the resistor reduces the current through the circuit and, therefore, reduces the available power. The resistor in some such embodiments is selected such that when any one of the switches is open, the available power is insufficient to operate the gas valve.

In some embodiments, the controller is configured to associate a signal received through the emitter with a condition in the appliance.

Some embodiments include a plurality of optocouplers each including an emitter and a receiver.

In some embodiments, a safety monitoring system is provided wherein a controller monitors the status of a plurality of optocouplers to detect a plurality of operating conditions. The receiver of the each optocoupler is connected to the microcontroller and each emitter is included in the leakage circuit of one of a plurality of switching units. The plurality of switching units is connectable in series between a power source and a load.

In some embodiments, the invention provides a safety string including a plurality of normally closed and normally open switches connected in series with and coupling power to a gas valve. A plurality of detection circuits includes a resistor, having a relatively high resistance, connected in series with an optocoupler. The detection circuits are connected across the switches. An output of each optocoupler is coupled to a microcontroller or other programmable device (e.g., microprocessor, digital signal processor, etc.). When a switch opens, due to a fault condition, power to the gas valve is removed, and the optocoupler associated with the switch provides an indication to the microcontroller of which switch is open regardless of the state of the other switches.

### BRIEF DESCRIPTION OF DRAWINGS

FIG. 1 is a block diagram of a gas fired water heater.

FIG. 2 is a schematic representation of a control system for the gas fired water heater in FIG. 1.

FIG. 3 is a schematic representation of a safety system capable of being used in the gas water heater of FIG. 1.

FIG. 4 is a functional illustration showing the flow of current in the safety system of FIG. 3, where all switches in the safety limit string are closed.

FIG. 5 is a functional illustration showing the flow of current in the safety system of FIG. 3, where multiple switches in the safety limit string are open.

### DETAILED DESCRIPTION

Before any embodiments of the invention are explained in detail, it is to be understood that the invention is not limited in its application to the details of construction and the arrangement of components set forth in the following description or illustrated in the following drawings. The invention is capable of other embodiments and of being practiced or of being carried out in various ways. Also, it is to be understood that the phraseology and terminology used herein is for the purposes of description and should not be regarded as limiting. The use of “including,” “comprising,” or “having” and variations thereof herein are meant to encompass the items listed thereafter and equivalents thereof as well as additional items. Unless specified or limited otherwise, the terms “mounted,” “connected,” “supported,” and “coupled” and variations thereof are used broadly and encompass both direct and indirect mountings, connections, supports, and couplings. Further, “connected” and “coupled” are not restricted to physical or mechanical connections or couplings.

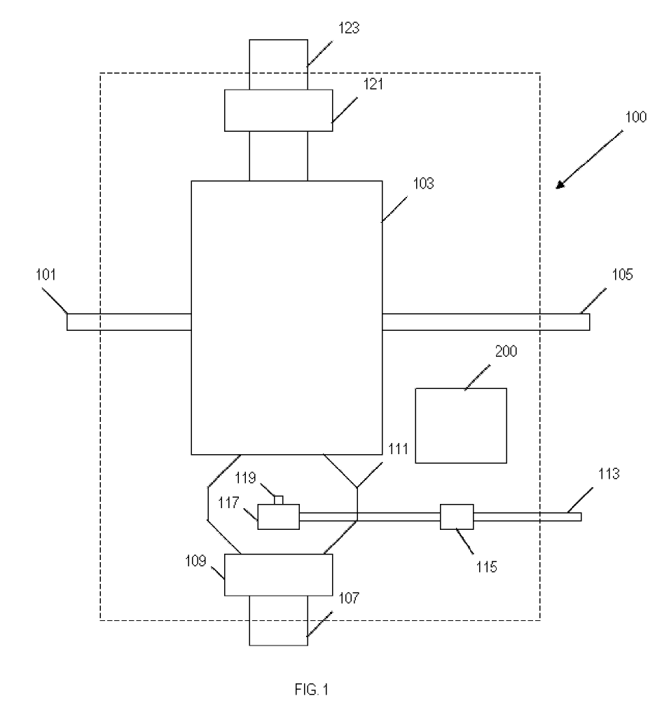

FIG. 1 shows one construction of a gas-fired water heater 100. Water heater 100 includes inlet pipe 101, which supplies unheated water to tank 103, and outlet pipe 105, which removes heated water from tank 103. Igniter 119 ignites gas burner 117 in combustion chamber 111 to heat the water. Gas valve 115 controls the flow of gas from gas inlet pipe 113 to burner 117. Blower 109 provides air from air inlet pipe 107 to combustion chamber 111. Vent 121 subsequently releases the air through air outlet pipe 123. The operation of water heater 100 is monitored and controlled by controller 200.

Although the constructions referred to herein describe a gas-fired water heater, the invention could be embodied in other gas-fired appliances such as, for example, a boiler, a furnace, and an oven. Other constructions of the invention could also be embodied in non-gas-fired systems, such as an electric water heater, that include type of electric load other than an electrically operated gas valve.

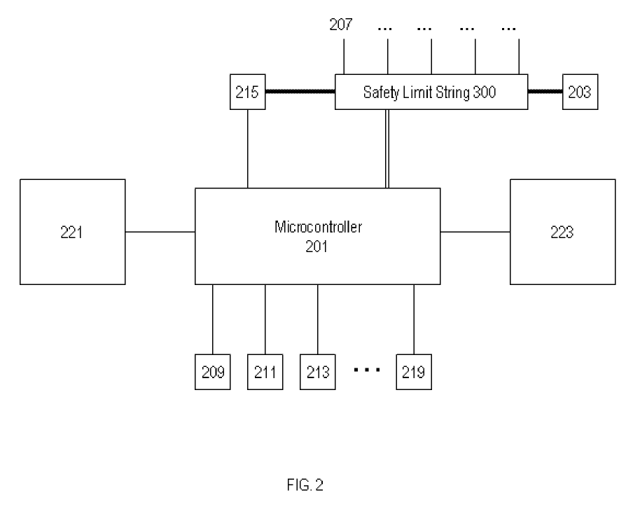

FIG. 2 shows one construction of controller 200 in greater detail. Microcontroller 201 is connected to user input device 221, user display/output device 223, electronically-controlled gas valve 215, and various other input sensors and controlled devices. Input sensors may include, for example, temperature sensor 209 which detects the temperature of the water in tank 103 and water level sensor 211 which detects the volume of water in tank 103. Controlled devices may include, for example, water pump 213 and igniter 219.

Safety limit string 300 is interposed between power source 203 and gas valve 215. Safety limit string 300 includes a plurality of normally open or normally closed switches arranged in series. All switches in safety limit string 300 should be closed before the gas valve can be sufficiently energized (i.e., opened). The switches are linked to various safety controls 207; for example, pressure switches connected in safety limit string 300 ensure proper blower air intake (blower 109) and exhaust pressures (vent 121). If a problem is detected, one of the switches opens (e.g., when a blower pressure is too low), power to the gas valve is reduced, and the gas valve closes.

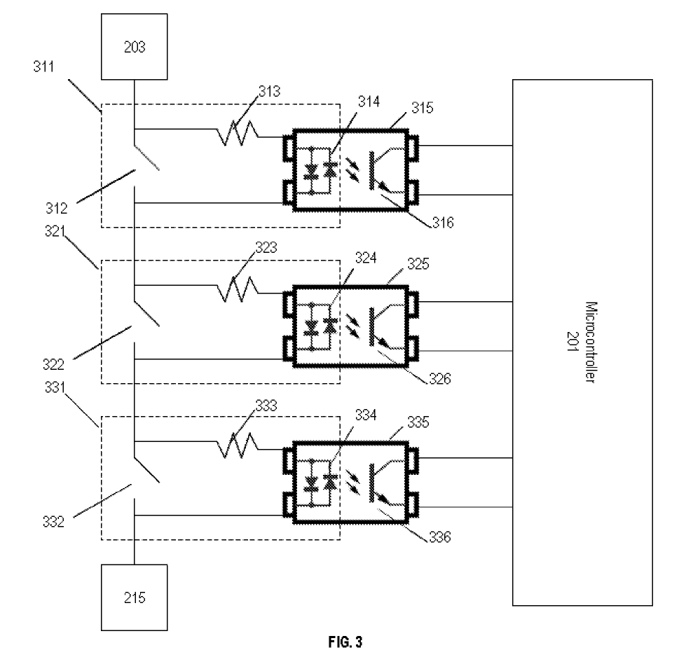

FIG. 3 provides a more detailed view of one construction of the safety limit string 300. A plurality of switching units (311, 321, and 331) are arranged in series between a 24 VAC power source 203 and a gas valve 215. Switching unit 311 includes two circuits arranged in parallel—a switch circuit and a leakage circuit. The switch circuit includes a switch 312 of relatively low resistance. The leakage circuit includes a resistor 313 having a relatively large resistance and the emitter of an optocoupler 315. The receiver of optocoupler 315 is connected to the microcontroller 201. Similar components in switching units 321 and 331 are labeled with similar reference characters.

An optocoupler (such as 315, 325, and 335) typically includes an emitter and a receiver. Referring to optocoupler 315 in FIG. 3, the emitter includes a light source such as LEDs 314. The receiver includes a light detector such as phototransistor 316. When current passes through the emitter, light is generated and detected by the receiver. Because the receiver is not conductively connected to the emitter, the circuit containing the emitter is separate from the circuit including the receiver. By connecting microcontroller 201 to the receiver of optocoupler 315, microcontroller 201 can determine when current is passing through the emitter without interfering with the safety limit string 300. As discussed in detail below, this construction allows current to continue through subsequent switching units so that the microcontroller 201 is able to detect multiple open switches at the same time.

Because the switch circuit in this construction is less resistant than the leakage circuit, little or no current flows through the leakage circuit if switch 312 is closed. Microcontroller 201 monitors optocoupler 315 and is configured to associate this condition with a closed switch 312. If switch 312 is open, current flows through the leakage circuit and the microcontroller 201 detects this current through optocoupler 315.

In some optocouplers (such as 315, 325, and 335), the amount of current detected on the receiver (e.g., the phototransistor 315) is proportional to the amount of current on the emitter (e.g., the LEDs 314); however, if the current on the emitter is below a certain threshold, no current is detected on the emitter. As such, in some constructions, components are selected such that when switch 312 is closed, no current is detected at optocoupler 315. In these constructions, the receiver of optocoupler 315 is connected to a digital input pin on microcontroller 201 and provides a high or low logic signal indicative of the status of switch 312.

In other constructions, the receiver of optocoupler 315 may detect a relatively small current even when switch 312 is closed. In such constructions, microcontroller 201 and associated circuitry on the receiver side of optocoupler 315 are configured to associate a current in excess of a predetermined threshold with an open switch. This comparison can be implemented by various methods including connecting the receiver of optocoupler 315 to a voltage or current comparator circuit that compares the detected current or voltage to a reference current or voltage. Such a comparator circuit is further configured to provide a high or low logic signal to microcontroller 201 indicative of the status of switch 312.

Alternatively, the receiver side of optocoupler 315 can be connected to an analog-to-digital converter on microcontroller 201. Microcontroller 201 can be configured to compare the value at the analog-to-digital converter to a predetermined threshold or can adaptively associate switches into “open” and “closed” groupings depending on the relative voltage or current detected at the corresponding optocoupler.

FIG. 3 shows an AC circuit construction in which optocoupler 315 includes two LEDs 314 (one for each direction in the alternating current) and a corresponding photodiode 316. Such optocoupler integrated circuits are commercially available in the PS2505 Multi Photocoupler Series produced by NEC Electronics, Inc. These components may include one or more optocouplers on the same IC. DC optocouplers are also available which include a single LED for each phototransistor. Still other optocoupler configurations utilize photodiodes instead of phototransistors.

In an example construction, switch 312 is a pressure switch monitoring air intake from blower 109, switch 322 is a pressure switch monitoring exhaust pressure from vent 121, and switch 332 is a bimetallic temperature switch configured to open if the temperature of the water in tank 103 exceeds a high-limit. It will be understood by those having ordinary skill in the art that safety limit string 300 may include various combinations of these and other switches and need not be assigned as in this construction.

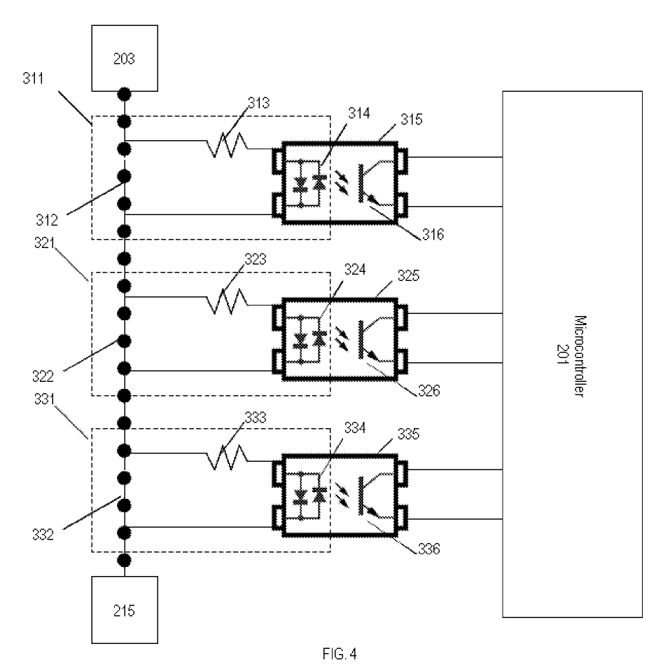

FIG. 4 illustrates the current flow through safety limit string 300 when all switches are closed. The flow of current is represented by the heavy dotted line. When all switches in safety limit string 300 are closed, current flows from power source 203 through low resistance switches 312, 322, and 332 and provides enough power to open gas valve 215. In this condition, microcontroller 201 can regulate gas flow by opening or closing gas valve 215. Microcontroller 201 can also confirm correct operation of blower 109 and vent 121 by monitoring optocouplers 315 and 325 respectively and can verify that the high-limit temperature has not been exceeded by monitoring optocoupler 335.

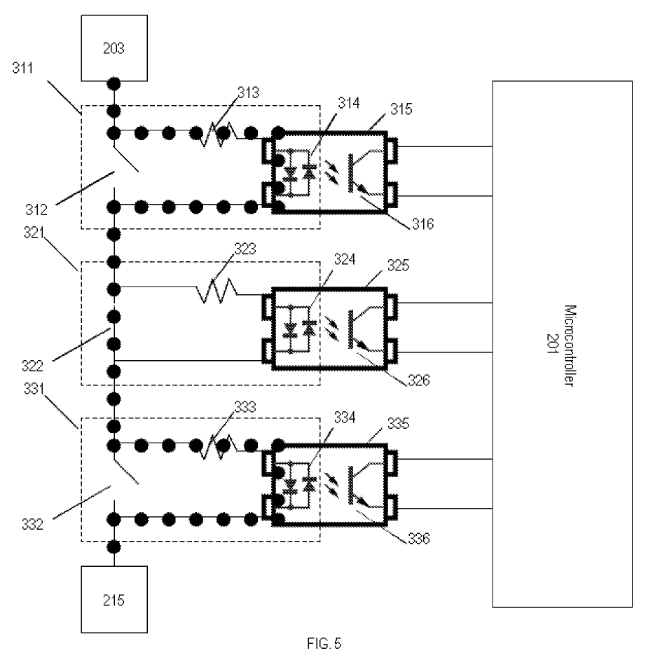

FIG. 5 illustrates the current flow through safety limit string 300 when switch 322 is closed, but switches 312 and 332 are open. Resistors 313, 323, and 333 in this construction have a high enough resistance such that when any one switch in the safety limit string 300 is open, the current through safety limit string 300 is reduced and the power is insufficient to energize (i.e., open) gas valve 215. Conversely, resistors 313, 323, and 333 have a low enough resistance such that when all of the switches in the safety limit string 300 are open, enough power remains such that the microcontroller 201 can detect current at optocouplers 315, 325, and 335.

Current flows through the leakage circuit in switching unit 311 and is detected by microcontroller 201 through optocoupler 315. Microcontroller 201 is configured to associate this condition with an insufficient intake pressure from blower 109. Current continues to switching unit 321 and passes through the switch circuit. Little or no current is directed through the leakage circuit and, as such, is not detected by microcontroller 201 through optocoupler 325. Microcontroller 201 is configured to associate this condition with a sufficient exhaust pressure at vent 121. Current then passes through the leakage circuit of switching unit 331 and is detected by microcontroller 201 through optocoupler 335. Microcontroller 201 is configured to associate this condition with a water temperature in tank 103 that exceeds the high-limit threshold. Finally, current arrives at gas valve 215. However, resistors 313 and 333 have reduced the current such that the available power is insufficient to operate the gas valve 215. Consequently, gas valve 215 remains closed and microcontroller 201 is aware of the adverse safety conditions.

It should be understood that the constructions described above are exemplary and other configurations and designs are possible. For example, although the above constructions describe an AC circuit, DC circuits might also be constructed. Furthermore, terms such as “resistor” and “emitter” are used broadly. Unless otherwise specified, the term “resistor,” for example, may refer to a single discrete component or it may refer to an arrangement of multiple components that together introduce resistance into a circuit. As such, additional components may be added to the describe circuit constructions without departing from the intended scope. Likewise, unless otherwise specified, the term “emitter,” for example, may refer to any device that emits a signal. Various features and advantages of the invention are set forth in the following claims.

What is claimed is:

1. A gas-fired appliance comprising:
a gas valve powered by a power source;
a first switching unit including
a first switch circuit including a first switch responsive to a first condition in the appliance, and
a first leakage circuit electrically connected in parallel with the first switch circuit, the first leakage circuit comprising a first resistor and a first emitter;
a first receiver configured to receive a first signal from the first emitter when the first switch is open and to communicate the first signal;
a second switching unit electrically connected in series with the power source, the gas valve, and the first switching unit, the second switching unit including
a second switch circuit including a second switch responsive to a second condition in the appliance, and
a second leakage circuit electrically connected in parallel with the second switch circuit, the second leakage circuit comprising a second resistor and a second emitter; and
a second receiver configured to receive a second signal from the second emitter when the second switch is open and to communicate the second signal.

2. The gas-fired appliance according to claim 1, further comprising a microcontroller configured to
receive the first signal from the first receiver;
associate the first signal with the first condition;
receive the second signal from the second receiver; and
associate the second signal with the second condition.

3. The gas-fired appliance according to claim 1, wherein the first resistor includes a high resistance that reduces the power in the circuit and prevents the gas valve from opening when the first switch is open.

4. The gas-fired appliance according to claim 3, wherein the second resistor includes a second high resistance that reduces the power in the circuit and prevents the gas valve from opening when the second switch is open.

5. The gas-fired appliance according to claim 1,
wherein the current passing through the first leakage circuit when both the first switch and the second switch are open is sufficient to enable the first emitter to emit the first signal that is received by the first receiver,
and wherein the current passing through the second leakage circuit when both the first switch and the second switch are open is sufficient to enable the second emitter to emit the second signal that is received by the second receiver.

6. The gas-fired appliance according to claim 1, wherein the first emitter includes a light emitting diode.

7. The gas-fired appliance according to claim 1, wherein the receiver includes a phototransistor.

8. The gas-fired appliance according to claim 1, further comprising an optocoupler integrated circuit including the first emitter and the first receiver.

9. The gas-fired appliance according to claim 8, wherein the optocoupler integrated circuit further includes the second emitter and the second receiver.

10. The gas-fired appliance according to claim 1, wherein the power source is external to the gas fired-appliance.

11. A safety monitoring system connectable to a power source and a load, the safety monitoring system comprising:
a plurality of optocouplers, each including an emitter and a receiver;
a plurality of switching units connectable in series between the power source and the load, each switching unit including
a switch circuit having a switch responsive to one of a plurality of operating conditions, and
a leakage circuit electrically connected in parallel with the switch circuit, the first leakage circuit comprising a resistor and the emitter of one of the plurality of optocouplers; and
a controller configured to monitor the receivers of the plurality of optocouplers and associate a signal from each optocoupler with one of the plurality of operating conditions.

12. The safety monitoring system of claim 11, wherein the resistor in the leakage circuit of each of the plurality of switching units has a respective high resistance that reduces the power in the safety control system and prevents the load from operating when the switch in the switch circuit of one of the plurality of switching units is open.

13. The safety monitoring system of claim 11, wherein current passes through each of the plurality of switching units despite an open switch in one of the previous switching units.

14. The safety monitoring system of claim 11, wherein the load includes a gas valve.

15. The safety monitoring system of claim 14, wherein the gas valve supplies fuel to a heat source of a gas-fired water heater.

16. A method of detecting one or more open switches in a safety limit string, the safety limit string including
a first switching unit including
a first switch circuit including a first switch, and
a first leakage circuit electrically connect in parallel with the first switch circuit, the first leakage circuit including an emitter of a first optocoupler; and
a second switching unit electrically connected in series with a power source, a load, and the first switching unit, the second switching unit including
a second switch circuit including a second switch, and
a second leakage circuit electrically connect in parallel with the second switch circuit, the second leakage circuit including an emitter of a second optocoupler;
the method comprising:
monitoring the first optocoupler;
detecting an open first switch when the first optocoupler indicates current passing through the first leakage circuit;
monitoring the second optocoupler;
detecting an open second switch when the second optocoupler indicates current passing through the second leakage circuit.

17. The method according to claim 16, further comprising:
associating the open first switch with a first condition, wherein the first switch is responsive to the first condition; and
associating the open second switch with a second condition, wherein the second switch is responsive to the second condition.

18. The method according to claim 16, wherein the safety limit string further includes a third switching unit electrically connected in series with a power source, a load, the first switching unit, and the second switching unit, the third switching unit including
a third switch circuit including a third switch, and
a third leakage circuit electrically connect in parallel with the third switch circuit, the third leakage circuit including an emitter of a third optocoupler;
the method further comprising:
monitoring the third optocoupler; and
detecting an open third switch when the third optocoupler indicates current passing through the first leakage circuit.

19. The method according to claim 16, wherein the first optocoupler is configured to indicate current passing through the first leakage circuit by communicating a first signal with an amplitude proportional to the current passing through the first leakage circuit, and
wherein detecting an open first switch includes comparing the amplitude of the first signal to a first threshold, the first threshold being indicative of the current associated with the open first switch.

20. The method according to claim 16, wherein the second optocoupler is configured to indicate current passing through the second leakage circuit by communicating a second signal with an amplitude proportional to the current passing through the second leakage circuit, and
wherein detecting an open second switch includes comparing the amplitude of the second signal to a second threshold, the second threshold being indicative of the current associated with the open second switch.
